(19) United States
(12) Patent Application Publication
(10) Pub. No.: US 2016/0173034 A1
(43) Pub. Date: Jun. 16, 2016

(54) AUDIO AMPLIFYING DEVICE

(71) Applicant: uPI Semiconductor Corp., Hsinchu County (TW)

(72) Inventor: Wen-Sheng Lin, Hsinchu County (TW)

(21) Appl. No.: 14/711,780

(22) Filed: May 14, 2015

(30) Foreign Application Priority Data
Dec. 11, 2014 (TW) 103143279

(51) Int. Cl. H03F 1/02; H03F 3/45; H03F 3/183

(52) U.S. Cl. CPC H03F 1/0205; H03F 3/183; H03F 3/45076; H03F 2200/03; H03F 2203/45116

(57) ABSTRACT

An audio amplifying device including a first differential amplifier, a first buffer and a common-mode feedback circuit is provided. The first differential amplifier generates a differential output signal according to a differential input signal, wherein the differential output signal includes a first output signal and a second output signal. The first buffer generates an audio signal according to the first output signal. The common-mode feedback circuit, the first buffer and the first differential amplifier form a feedback loop, and the audio amplifying device controls a bias state of the first differential amplifier through the feedback loop so as to adjust a DC level of the audio signal to a clamping voltage.

### CROSS-REFERENCE TO RELATED APPLICATION

This application claims the priority benefit of Taiwan application serial no. 103143279, filed on Dec. 11, 2014. The entirety of the above-mentioned patent application is hereby incorporated by reference herein and made a part of this specification.

### BACKGROUND OF THE INVENTION

1. Field of the Invention

The present invention generally relates to an audio amplifying device, in particular, to an audio amplifying device configured to be operated in the capless mode.

2. Description of Related Art

Audio amplifying device can be divided into a cap-mode configuration and a capless-mode configuration according to the driving configuration. For example, FIG. 1 is a schematic diagram of an audio amplifying device in application. As shown in the upper part of FIG. 1, the audio amplifying device 110 is operated in the capless mode so that the audio amplifying device 110 can drive the back-end load 101 through DC-coupled manner. On the other hand, as shown in the lower part of FIG. 1, the audio amplifying device 120 is operated in the cap mode. Therefore, the coupling capacitor 130 must be disposed between the audio amplifying device 120 and the load 101 so that the audio amplifying device 120 drives the back-end load 101 through AC-coupled manner.

In other words, the audio amplifying device operated in the capless mode cannot directly drive the back-end load and the coupling capacitor must be additionally provided thus to increase the application cost of the audio amplifying device. Further, the audio amplifying device in applications may be influenced by crosstalk in environment thereby reducing its output quality. Therefore, how to design an audio amplifying device suitable in the capless mode and to improve ability of eliminating crosstalk for the audio amplifying device is one of the major subjects to which people skilled in the art are dedicated.

### SUMMARY OF THE INVENTION

The invention provides an audio amplifying device that adjusts a DC level of an audio signal by using a feedback loop formed by a common-mode feedback circuit, a buffer, and differential amplifier. In this way, the audio amplifying device is adapted to be operated in the capless mode, thereby reducing application costs. In addition, the audio amplifying device receives a differential input signal by a differential amplifier thus to improve the ability of eliminating crosstalk.

An audio amplifying device of the invention comprises a first differential amplifier, a first buffer and a common-mode feedback circuit. The first differential amplifier generates a differential output signal according to a differential input signal, wherein the differential output signal includes a first output signal and a second output signal. The first buffer generates an audio signal according to the first output signal. The common-mode feedback circuit, the first buffer and the first differential amplifier form a feedback loop, and the audio amplifying device controls a bias state of the first differential amplifier through the feedback loop so as to adjust a DC level of the audio signal to a clamping voltage.

According to another aspect, an audio amplifying device of the invention has a single-ended output terminal and comprises a first differential amplifier, a first buffer and a common-mode feedback circuit. The first differential amplifier have a first input terminal, a second input terminal, a first output terminal and a second output terminal and output a first output signal and a second output signal through the first output terminal and the second output terminal. The first buffer is coupled between the first output terminal and the single-ended output terminal, and generates an audio signal according to the first output signal. The common-mode feedback circuit is coupled to the single-ended output terminal, the second output terminal and the second input terminal to form a feedback loop. The audio amplifying device controls a bias state of the first differential amplifier through the feedback loop so as to adjust a DC level of the audio signal to a clamping voltage and outputs the audio signal through the single-ended output terminal in unbalanced manner.

Based on the above description, the audio amplifying device of the invention adjusts the DC level of the audio signal by using the feedback loop formed by the common-mode feedback circuit, the buffer, and the differential amplifier. In this way, the audio amplifying device is adapted to be operated in the capless mode, thereby reducing application costs. In addition, the audio amplifying device receives the differential input signal by the differential amplifier thus to improve the ability of eliminating crosstalk.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of an audio amplifying device application.

FIG. 2 is a schematic diagram of an audio amplifying device according to an embodiment of the invention.

FIG. 3 is a schematic diagram of a part of an audio amplifying device according to an embodiment of the invention.

FIG. 4 is a schematic diagram of a part of an audio amplifying device according to another embodiment of the invention.

FIG. 5 is a schematic diagram of a part of an audio amplifying device according to yet another embodiment of the invention.

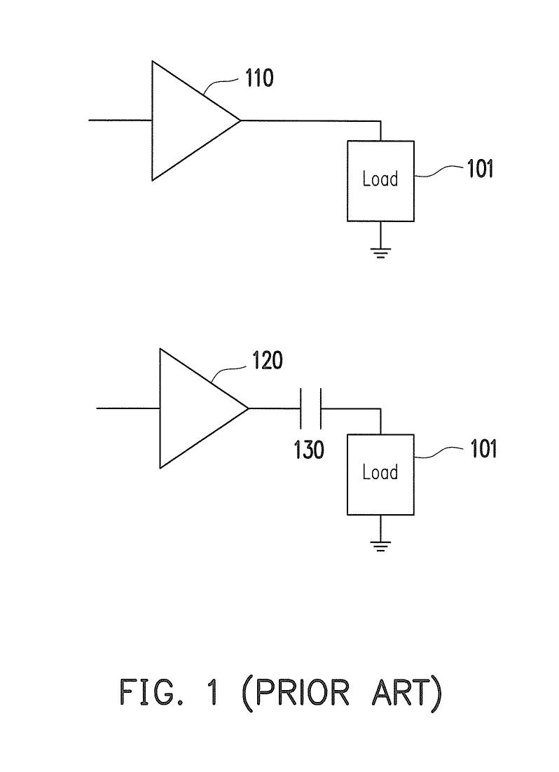

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

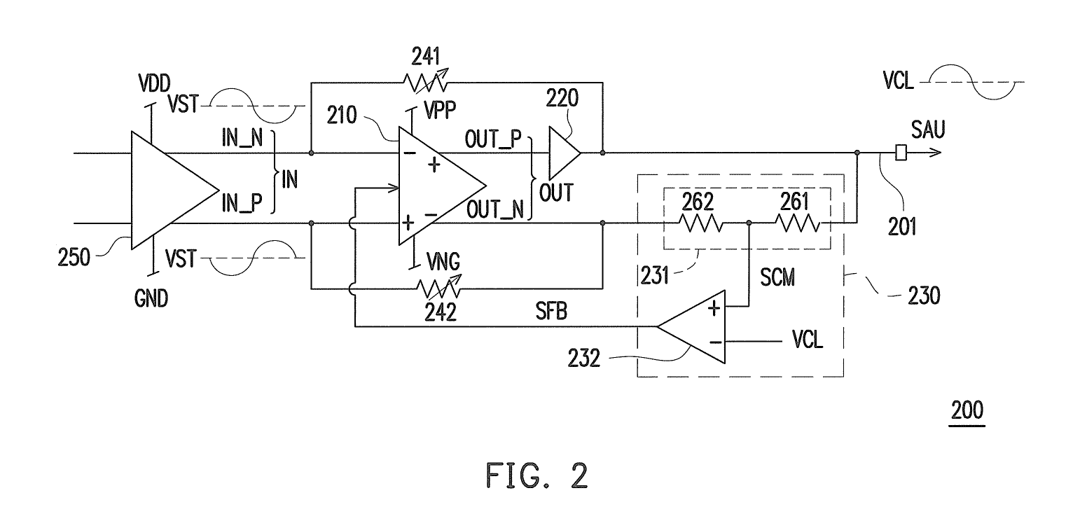

FIG. 2 is a schematic diagram of an audio amplifying device according to an embodiment of the invention. As shown in FIG. 2, an audio amplifying device 200 has a single-ended output terminal 201 and can outputs an audio signal SAU through the single-ended output terminal 201 in unbalanced manner. In addition, the audio amplifying device 200 includes a differential amplifier 210, a buffer 220 and a common-mode feedback circuit 230. The differential amplifier 210 may be, for example, a class AB amplifier. Besides, the differential amplifier 210 will generate a differential output signal OUT according to a differential input signal IN. For example, the differential input signal IN includes a first input signal IN_N and a second input signal IN_P, and the first input terminal and the second input terminal of the differential amplifier 210 receive the first input signal IN_N and the second input signal IN_P. In contrast, the differential output signal OUT includes a first output signal OUT_P and a second output signal OUT_N, and the first output terminal and the second output terminal of the differential amplifier 210 output the first output signal OUT_P and the second output signal OUT_N.

The buffer 220 is coupled between the first output terminal of the differential amplifier 210 and the single-ended output terminal 201 of the audio amplifying device 200. In addition, the buffer 220 generates an audio signal SAU according to the first output signal OUT_P. Further, the common-mode feedback circuit 230 is electrically connected to the single-ended output terminal 201 of the audio amplifying device 200, the second output terminal and the second input terminal of the differential amplifier 210 to form a feedback loop. Namely, the common-mode feedback circuit 230, the buffer 220 and the differential amplifier 210 can form the feedback loop. The audio amplifying device 200 controls a bias state of the differential amplifier 210 through the feedback loop so as to adjust a DC level of the audio signal SAU to a clamping voltage VCL.

For example, a DC level of the differential input signal IN received by the differential amplifier 210 equals to a reference voltage VST (for example, 0.9 V), and the amplitude range of the differential input signal may be, for example, from 0 V to 1.8 V. Further, the DC Level of the audio signal SAU outputted by the differential amplifier 210 will be adjusted to the clamp voltage VCL (e.g., 0 V) through the feedback loop, and the amplitude range of the audio signal SAU may be, for example, from −0.9 V to 0.9 V.

In other words, the audio amplifying device 200 can adjust the DC Level of the audio signal SAU through the feedback loop. Accordingly, the audio amplifying device 200 can directly use the audio signal SAU to drive the back-end load in application, and therefore the audio amplifying device 200 can be operated in the capless mode, thereby effectively reducing application costs of the audio amplifying device 200. Further, the audio amplifying device 200 also can be coupled to a coupling capacitor and drive the back-end load through the coupling capacitor in application, and therefore the audio amplifying device 200 can be applied in cap mode.

In addition, the differential amplifier 210 has a differential input structure so that the differential amplifier 210 has better anti-noise capability thus improving the ability of eliminating crosstalk. Furthermore, the audio signal SAU outputted by the audio amplifying device 200 is a single-ended signal. In other words, the audio amplifying device 200 is an audio amplifying device with single-ended output. Therefore, connected lines between the audio amplifying device 200 and the back-end load can be effectively reduced in application thereby reducing application costs.

Furthermore, the audio amplifying device 200 further includes a variable resistor 241, a variable resistor 242 and a differential amplifier 250. The variable resistor 241 is coupled between the first input terminal of the differential buffer amplifier 210 and the output terminal of the buffer 220, and the variable resistor 242 is coupled between the second input terminal and the second output terminal of the differential amplifier 210. The audio amplifying device 200 can adjust its operating characteristics via the variable resistor 241 and the variable resistor 242.

The differential amplifier 250 generates the differential input signal IN. Since the DC Level of the differential input signal IN is different from the DC level of the audio signal SAU, the differential amplifier 250 and differential amplifier 210 are respectively operated at different power voltages. For example, in one embodiment, the differential amplifier 210 is operated at power voltage VPP (e.g., 0.9 V) and power voltage VNG (e.g., −0.9 V), and the differential amplifier 250 is operated at power voltage VDD (e.g., 1.8 V) and power voltage GND (e.g., 0 V).

Referring again to FIG. 2, the common-mode feedback circuit 230 includes a detector 231 and a differential amplifier 232. The detector 231 detects a common-mode signal SCM between the audio signal SAU and the second output signal OUT N. For example, the detector 231 includes a resistor 261 and a resistor 262. The first terminal of the resistor 261 receives the audio signal SAU, the second terminal of the resistor 261 is coupled to the first terminal of the resistor 262, and the second terminal of the resistor 262 receives the second output signal OUT_N. In this way, the detector 231 detects the average between the audio signal SAU and the second output signal OUT_N through the resistor 261 and 262, thereby generating the common-mode signal SCM through the second terminal of the resistor 261.

The first terminal of the differential amplifier 232 receives the common-mode signal SCM and the second terminal of the differential amplifier 232 receives the clamping voltage VCL. In addition, the differential amplifier 232 generates the feedback signal SFB in response to the common-mode signal SCM and the clamping voltage VCL to control the bias state of the differential amplifier 210. In this way, the DC Level of the audio signal SAU will be gradually approach to the clamping voltage VCL in response to the characteristics of the differential amplifier 232 which is a virtual short circuit of two input terminal.

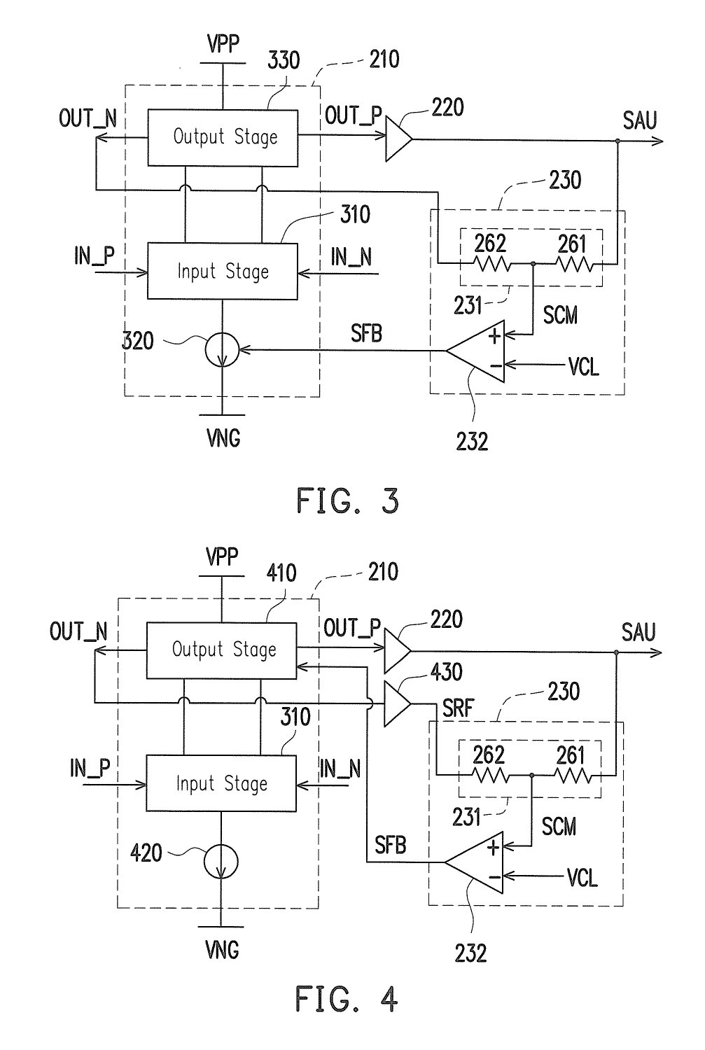

It should be noted that the common-mode feedback circuit 230 can control the bias state of the differential amplifier 210 through controlling an output stage or a current source of the differential amplifier 210. For example, FIG. 3 is a schematic diagram of a part of an audio amplifying device according to an embodiment of the invention. As shown in FIG. 3, the differential amplifier 210 includes an input stage 310, a current source 320 and an output stage 330. The input stage 310 receives the differential input signal IN. The current source 320 is coupled to the input stage 310 for providing a bias current. The output stage 330 is coupled to the input stage 310 for generating the differential output signal OUT. In operation, the input stage 310 can control the current flowing through the input stage 310 according to the differential input signal IN to cause the output stage 330 generating the corresponding differential output signal OUT. In addition, the differential amplifier 210 controls the bias current generated by the current source 320 according to the feedback signal SFB to adjust the bias state. In other words, the common-mode feedback circuit 230 can control the bias state of the differential amplifier 210 through controlling the current source 320 in the differential amplifier 210.

Moreover, FIG. 4 is a schematic diagram of a part of an audio amplifying device according to another embodiment of the invention. In the embodiment of FIG. 4, the output stage 410 in the differential amplifier 210 is at least biased at a bias voltage, and the differential amplifier 210 uses the feedback signal SFB as the bias voltage to adjust its bias state. In addition, the current source 420 in embodiment of FIG. 4 is not under control of the common-mode feedback circuit 230. In other words, the common-mode feedback circuit 230 can control the bias state of the differential amplifier 210 through controlling the output stage 330 of the differential amplifier 210. Detailed description regarding elements in the differential amplifier 210 in the embodiment of FIG. 4 has been included in above embodiment, thus it is omitted hereinafter.

It should be noted that, in view of the audio amplifying device 200 in FIG. 2 and FIG. 3, a single buffer 220 is disposed in the back-end of the differential amplifier 210, and the common-mode feedback circuit 230 generates the feedback signal SFB through detecting the audio signal SAU and the second output signal OUT N. However, in another embodiment, two buffers can be disposed in the back-end of the differential amplifier 210, and the common-mode feedback circuit 230 can generates the feedback signal SFB through detecting output signals of the two buffers.

For example, the audio amplifying device 200 further includes a buffer 430 in embodiment of FIG. 4. The buffer 430 generates a reference signal SRF according to the second output signal OUT_N. The detector 231 can detect the common-mode signal SCM between the audio signal SAU and the reference signal SRF. The differential amplifier 232 generates the feedback signal SFB according to the common-mode signal SCM and the clamping voltage VCL. In other words, the common-mode feedback circuit 230 generates the feedback signal SFB through detecting output signals SRF and SAU of the two buffers 220 and 430 in FIG. 4.

In addition, the driving capability of the buffer 430 is less than the driving capability of the buffer 220. That is, in one embodiment, the size of the buffer 430 is smaller than the size of the buffer 220, thereby reducing the design cost of the audio amplifying device 200. In a similar manner, people skilled in the art can selectively set an additional buffer in the embodiment of FIG. 2 and FIG. 3 according to requirement of design so that the additional buffer amplifies the second output signal OUT_N, and the common-mode feedback circuit 230 generates the feedback signal SFB through detecting the output signals of the two buffers.

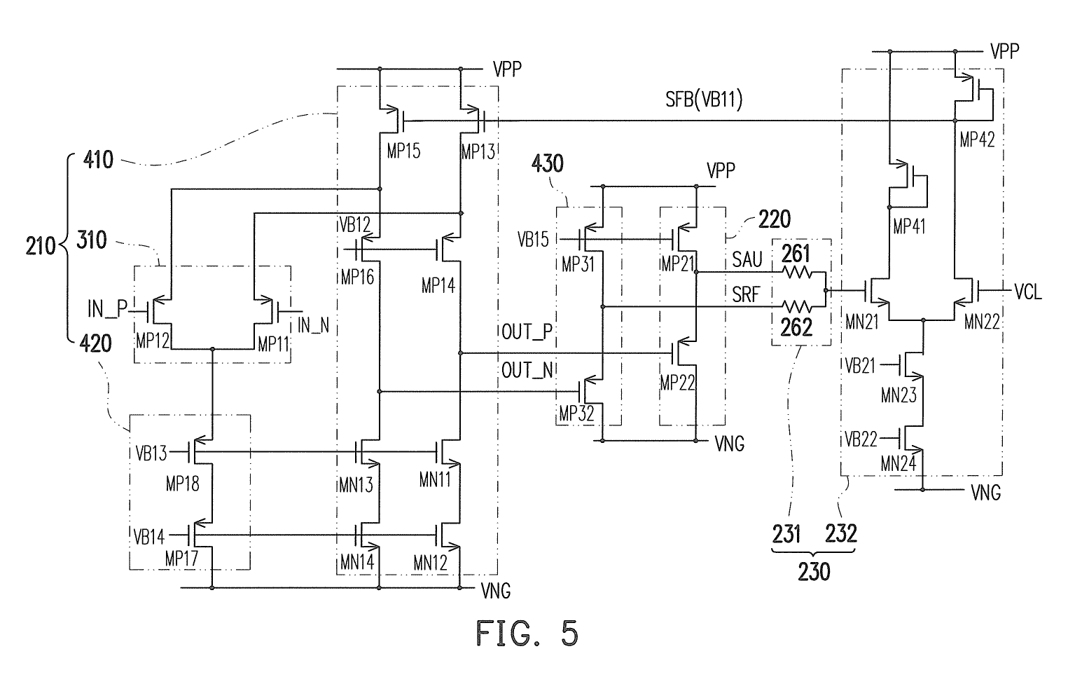

In order to fully convey the spirit of the invention to those skilled in the art, FIG. 5 is a schematic diagram of a part of an audio amplifying device according to yet another embodiment of the invention. The following will be described with FIG. 5 to illustrate the detailed structure of the input stage 310, the output stage 410, the current source 420, the buffer 220, the buffer 430 and the differential amplifier 432 in FIG. 4.

As shown in FIG. 5, the input stage 310 includes a P-type transistor MP 11 and a P-type transistor MP12. The first terminal of the P-type transistor MP 11 is coupled to the current source 420, the second terminal of the P-type transistor MP11 is coupled to the output stage 410, and the control terminal of the P-type transistor MP11 receives the first input signal INN. The first terminal of the P-type transistor MP12 is coupled to the first terminal of the P-type transistor MP11, the second terminal of the P-type transistor MP12 is coupled to the output stage 410, and the control terminal of the P-type transistor MP12 receives the second input signal IN_P. The differential amplifier 210 can form a differential pair through the P-type transistors MP11 and MP12 to receive the differential input signal IN.

The output stage 410 includes P-type transistors MP13˜MP16 and N-type transistors MP11˜MP14. The first terminal of the P-type transistor MP13 is coupled to the second terminal of the P-type transistor MP11, the second terminal of the P-type transistor MP13 receives the power voltage VPP, and the control terminal of the P-type transistor MP13 receives the bias voltage VB11 (i.e., the feedback signal SFB). The first terminal of the P-type transistor MP 14 outputs the first output signal OUT_P, the second terminal of the P-type transistor MP14 is coupled to the first terminal of the P-type transistor MP13, and the control terminal of the P-type transistor MP14 receives the bias voltage VB 12. The first terminal of the P-type transistor MP15 is coupled to the second terminal of the P-type transistor MP12, the second terminal of the P-type transistor MP15 receives the power voltage VPP, and the control terminal of the P-type transistor MP15 receives the bias voltage VB11. The first terminal of the P-type transistor MP16 outputs the second output signal OUT_N, the second terminal of the P-type transistor MP16 is coupled to the first terminal of the P-type transistor MP15, and the control terminal of the P-type transistor MP16 receives the bias voltage VB12.

The first terminal of the N-type transistor MN11 is coupled to the first terminal of the P-type transistor MP14 and the control terminal of the N-type transistor MN11 receives the bias voltage VB13. The first terminal of the N-type transistor MN12 is coupled to the second terminal of the N-type transistor MN11, the second terminal of the N-type transistor MN12 receives the power voltage VNG, and the control terminal of the N-type transistor MN12 receives the bias voltage VB14. The first terminal of the N-type transistor MN13 is coupled to the first terminal of the P-type transistor MP16 and the control terminal of the N-type transistor MN 13 receives the bias voltage VB13. The first terminal of the N-type transistor MN14 is coupled to the second terminal of the N-type transistor MN13, the second terminal of the N-type transistor MN14 receives the power voltage VNG, and the control terminal of the N-type transistor MN14 receives the bias voltage VB14. Therefore, the output stage 410 can form folded cascade structure thus to increase the output impedance of the differential amplifier 210, so as to enhance the gain of the differential amplifier 210.

The current source 420 includes a P-type transistor MP17 and a P-type transistor MP18. The first terminal of the P-type transistor MP17 receives the power voltage VNG and the control terminal of the P-type transistor MP17 receives the bias voltage VB14. The first terminal of the P-type transistor MP18 is coupled to the second terminal of the P-type transistor MP17, the second terminal of the P-type transistor MP18 is coupled to the first terminal of the P-type transistor MP11, and the control terminal of the P-type transistor MP18 receives the bias voltage VB13. The P-type transistor MP17 and the P-type transistor MP18 are respectively biased at the bias voltage VB14 and the bias voltage VB13 thereby generating bias current.

The buffer 220 includes a P-type transistor MP21 and a P-type transistor MP22. The first terminal of the P-type transistor MP21 outputs the audio signal SAU, the second terminal of the P-type transistor MP21 receives the power voltage VPP, and the control terminal of the P-type transistor MP21 receives the bias voltage VB15. The first terminal of the P-type transistor MP22 receives the power voltage VNG, the second terminal of the P-type transistor MP22 is coupled to the first terminal of the P-type transistor MP21, and the control terminal of the P-type transistor MP22 is coupled to the first terminal of the P-type transistor MP14 to receive the first output signal OUT_P.

Similarly, the buffer 430 can also be composed of two P-type transistors MP31 and MP32. The P-type transistors MP31 and MP32 are connected in series with each other. The control terminal of the P-type transistor MP31 receives the bias voltage VB15 and the control terminal of the P-type transistor MP32 is coupled to the first terminal of the P-type transistor MP 16 to receive the second output signal OUT_N. In addition, in one embodiment, the driving capability of the buffer 430 is less than the driving capability of the buffer 220. Therefore, both the size of the P-type transistors MP31 and MP32 in the buffer 430 are respectively smaller than the size of the P-type transistors MP21 and MP22 in the buffer 220.

The differential amplifier 232 includes N-type transistors MN21˜MN24, a P-type transistor MP41, and a P-type transistor MP42. The control terminal of the N-type transistor MN21 is coupled to the second terminal of the resistor 261 to receive the common-mode signal SCM. The control terminal of the N-type transistor MN22 receives the clamping voltage VCL. The first terminal of the P-type transistor MP41 is coupled to the first terminal of the N-type transistor MN21, the second terminal of the P-type transistor MP41 receives the power voltage VPP, and the control terminal of the P-type transistor MP41 is electrically connected to the first terminal. The first terminal of the P-type transistor MP42 is coupled to the first terminal of the N-type transistor MN22, the second terminal of the P-type transistor MP42 receives the power voltage VPP, and the control terminal of the P-type transistor MP42 is electrically connected to the first terminal.

The first terminal of the N-type transistor MN23 is coupled to the second terminal of the N-type transistor MN21 and the second terminal of the N-type transistor MN22 and the control terminal of the N-type transistor MN23 receives the bias voltage VB21. The first terminal of the N-type transistor MN24 is coupled to the second terminal of the N-type transistor MN23, the second terminal of the N-type transistor MN24 receives the power voltage VNG, and the control terminal of the N-type transistor MN24 receives the bias voltage VB22. The differential amplifier 232 can form a differential pair through the N-type transistors MN21 and MN22 to receive the common-mode signal SCM and the clamping voltage VCL. The N-type transistors MN23 and MN24 provide a bias current. The P-type transistors MP41 and MP42 form active loads so that the differential amplifier 232 generates the feedback signal SFB through the first terminal of the P-type transistor MP42.

To sum up, the embodiments of the present invention provide an audio amplifying device to control the bias state of the differential amplifier by using the feedback loop formed by a common-mode feedback circuit, a buffer, and a differential amplifier so as to adjust the DC level of the audio signal to a clamping voltage. In this way, the audio amplifying device can directly drive the back-end load by using the audio signal, and thus the audio amplifying device is adapted to be operated in the capless mode thereby reducing application costs of the audio amplifying device. In addition, the audio amplifying device of the present invention have single-ended output configuration which effectively reduced connection lines between the audio amplifying device and the back-end load, and thus may further reduce application costs of audio amplifying device. Furthermore, the differential amplifier receives the differential input signal by using the differential input structure which can improve the ability of eliminating crosstalk for the audio amplifying device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. An audio amplifying device, comprising:
a first differential amplifier, generating a differential output signal according to a differential input signal, wherein the differential output signal includes a first output signal and a second output signal;
a first buffer, generating an audio signal according to the first output signal; and
a common-mode feedback circuit, wherein the common-mode feedback circuit, the first buffer, and the first differential amplifier form a feedback loop, and the audio amplifying device controls a bias state of the first differential amplifier through the feedback loop so as to adjust a DC level of the audio signal to a clamping voltage.

2. The audio amplifying device of claim 1, wherein the common-mode feedback circuit comprises:
a detector, detecting a common-mode signal between the audio signal and the second output signal; and
a second differential amplifier, generating a feedback signal according to the common-mode signal and the clamping voltage, wherein the second differential amplifier uses the feedback signal to control an output stage or a current source in the first differential amplifier.

3. The audio amplifying device of claim 1, wherein the audio amplifying device further comprises a second buffer, the second buffer generates a reference signal according to the second output signal and the common-mode feedback circuit comprises:
a detector, detecting a common-mode signal between the audio signal and the reference signal; and
a second differential amplifier, generating a feedback signal according to the common-mode signal and the clamping voltage, wherein the second differential amplifier uses the feedback signal to control an output stage or a current source in the first differential amplifier.

4. The audio amplifying device of claim 3, wherein the driving capability of the second buffer is less than the driving capability of the first buffer.

5. The audio amplifying device of claim 1, wherein the first differential amplifier comprises:
an input stage, receiving the differential input signal;
a current source, coupled to the input stage and providing a bias current; and
an output stage, coupled to the input stage and at least biased at a first bias voltage to generate the differential output signal, wherein the common-mode feedback circuit generates a feedback signal through the feedback loop, and the first differential amplifier controls the bias current according to the feedback signal or uses the feedback signal as the first bias voltage.

6. The audio amplifying device of claim 1, wherein a first input terminal and a second input terminal of the first differential amplifier receive the differential input signal, a first output terminal and a second output terminal of the first differential amplifier output the differential output signal and the audio amplifying device further comprises:
a first variable resistor, coupled to between the first input terminal of the first differential amplifier and the output terminal of the first buffer; and
a second variable resistor, coupled to between the second input terminal and the second output terminal of the first differential amplifier.

7. The audio amplifying device of claim 1, further comprising a second differential amplifier, wherein the second differential amplifier generates the differential input signal and a DC level of the differential input signal is different from the DC level of the audio signal.

8. The audio amplifying device of claim 1, wherein the audio amplifying device is configured to be operated in a capless mode.

9. An audio amplifying device, having a single-ended output terminal, and comprising:
a first differential amplifier, having a first input terminal, a second input terminal, a first output terminal and a second output terminal, and outputting a first output signal and a second output signal through the first output terminal and the second output terminal;
a first buffer, coupled between the first output terminal and the single-ended output terminal, and generated an audio signal according to the first output signal; and
a common-mode feedback circuit, coupled to the single-ended output terminal, the second output terminal and the second input terminal to form a feedback loop, wherein the audio amplifying device controls a bias state of the first differential amplifier through the feedback loop so as to adjust a DC level of the audio signal to a clamping voltage and outputs the audio signal through the single-ended output terminal in unbalanced manner.

10. The audio amplifying device of claim 9, wherein the common-mode feedback circuit comprises:
a detector, detecting a common-mode signal between the audio signal and the second output signal; and
a second differential amplifier, generating a feedback signal according to the common-mode signal and the clamping voltage, wherein the second differential amplifier uses the feedback signal to control an output stage or a current source in the first differential amplifier.

11. The audio amplifying device of claim 9, wherein the audio amplifying device further comprises a second buffer, the second buffer generates a reference signal according to the second output signal and the common-mode feedback circuit comprises:
a detector, detecting a common-mode signal between the audio signal and the reference signal; and
a second differential amplifier, generating a feedback signal according to the common-mode signal and the clamping voltage, wherein the second differential amplifier uses the feedback signal to control an output stage or a current source in the first differential amplifier.

12. The audio amplifying device of claim 11, wherein the driving capability of the second buffer is less than the driving capability of the first buffer.

13. The audio amplifying device of claim 9, wherein the first differential amplifier comprises:
an input stage, receiving a differential input signal;
a current source, coupled to the input stage and providing a bias current; and
an output stage, coupled to the input stage and at least biased at a first bias voltage to generate the first output signal and the second output signal, wherein the common-mode feedback circuit generates a feedback signal through the feedback loop, and the first differential amplifier controls the bias current according to the feedback signal or uses the feedback signal as the first bias voltage.
